(19) United States
(12) Patent Application Publication
(10) Pub. No.: US 2014/0104504 A1
(43) Pub. Date: Apr. 17, 2014

(54) TELEVISION AND ELECTRONIC APPARATUS

(71) Applicant: Kabushiki Kaisha Toshiba, Tokyo (JP)

(72) Inventor: Naoki Kuwajima, Hamura-shi (JP)

(73) Assignee: Kabushiki Kaisha Toshiba, Tokyo (JP)

(21) Appl. No.: 14/030,778

(22) Filed: Sep. 18, 2013

Related U.S. Application Data
(63) Continuation of application No. PCT/JP2013/068457, filed on Jun. 28, 2013.

(30) Foreign Application Priority Data
Oct. 11, 2012 (JP) 2012-226180

(51) Int. Cl. G02F 1/1333; H04N 5/64; H05K 5/02

(52) U.S. Cl. CPC G02F 1/133308; H05K 5/0217; H04N 5/64
USPC 348/843

(57) ABSTRACT

According to one embodiment, an electronic apparatus includes a housing which includes a front bezel. A display panel and a middle frame are contained in the housing. The middle frame includes a support face which supports an outer circumferential part of the display panel, and is configured to sandwich and hold the outer circumferential part of the display panel between the support face and the front bezel. A reinforcing member is attached to the middle frame. The reinforcing member reinforces the middle frame and is fixed to the front bezel through a connecting member.

### CROSS REFERENCE TO RELATED APPLICATIONS

This application is a Continuation Application of PCT Application No. PCT/JP2013/068457, filed Jun. 28, 2013 and based upon and claiming the benefit of priority from Japanese Patent Application No. 2012-226180, filed Oct. 11, 2012, the entire contents of all of which are incorporated herein by reference.

### FIELD

Embodiments described herein relate generally to a television and an electronic apparatus.

### BACKGROUND

A liquid crystal television comprises a liquid crystal panel which displays images. The liquid crystal panel is held on a housing by a middle frame. The middle frame and a front bezel of the housing sandwich an outer circumferential part of the liquid crystal panel.

According to the conventional liquid crystal television, the middle frame may damage the liquid crystal panel when holding the liquid crystal panel on the housing. Therefore, the middle frame needs to be carefully assembled onto the liquid crystal panel. There is room for improvement in efficiently performing work of assembling the liquid crystal television.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1A is an exemplary front view of a liquid crystal television;

FIG. 1B is an exemplary side view of the liquid crystal television;

FIG. 2 is an exemplary sectional view of the liquid crystal television showing a status that a reinforcing member is fixed to a front bezel by pins;

FIG. 3 is an exemplary sectional view of the liquid crystal television showing a status that a back bezel is fixed to the reinforcing member by screws;

FIG. 4 is an exemplary sectional view of the liquid crystal television showing a status that a surface sheet of a light guide module is held on the back bezel;

FIG. 5 is an exemplary front view of the back bezel;

FIG. 6 is an exemplary front view of the middle frame;

FIG. 7 is an exemplary rear view of the middle frame reinforced by the reinforcing member;

FIG. 8 is an exemplary perspective view of the middle frame reinforced by the reinforcing member;

FIG. 9 is an exemplary perspective view showing a status that the reinforcing member is attached to the middle frame;

FIG. 10 is an exemplary perspective view showing a wall part and a pin receiving part of the front bezel; and

FIG. 11 is an exemplary perspective view showing a status that the middle frame is assembled in the front bezel.

### DETAILED DESCRIPTION

Various embodiments will be described hereinafter with reference to the accompanying drawings. In general, according to one embodiment, an electronic apparatus comprises a housing comprising a front bezel provided with an opening. A display panel and a middle frame are contained in the housing. The display panel comprises a screen exposed from the opening. The middle frame comprises a support face which supports an outer circumferential part of the display panel, and is configured to sandwich and hold an outer circumferential part of the display panel between the support face and the front bezel. A reinforcing member is attached to the middle frame. The reinforcing member reinforces the middle frame and is fixed to the front bezel by a connecting member.

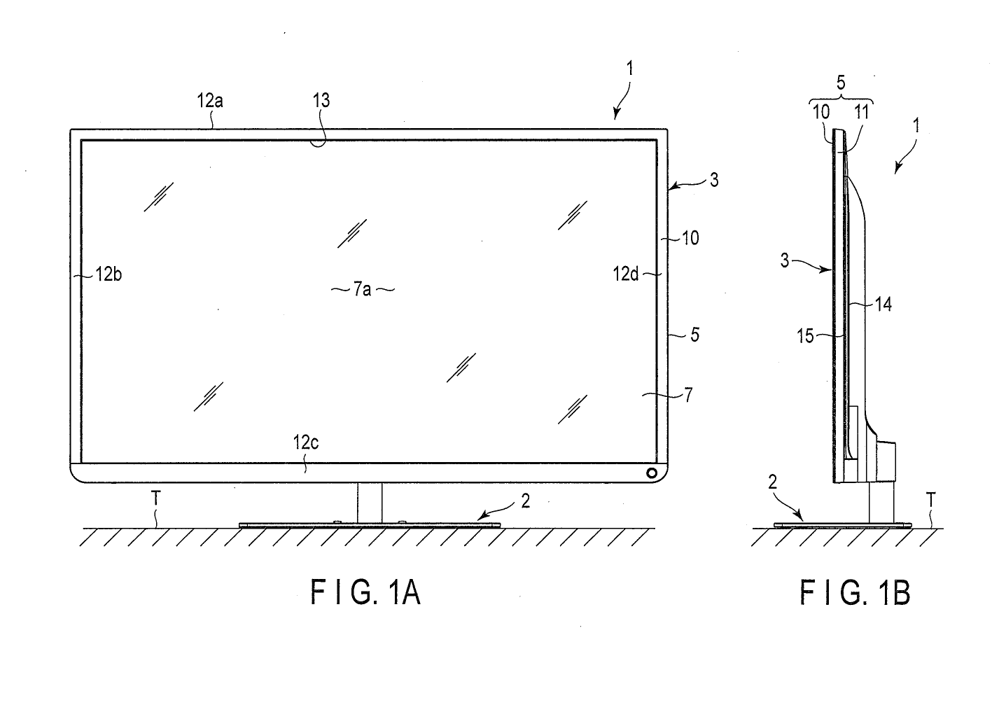

FIG. 1A and FIG. 1B disclose a liquid crystal television 1 according to an embodiment. The liquid crystal television 1 is an example of an electronic apparatus. The liquid crystal television 1 comprises a table stand 2 and a television body 3. The table stand 2 is secured to, for example, a top plate T of a television table. The television body 3 is supported by the table stand 2 so as to stand vertically on the top plate T.

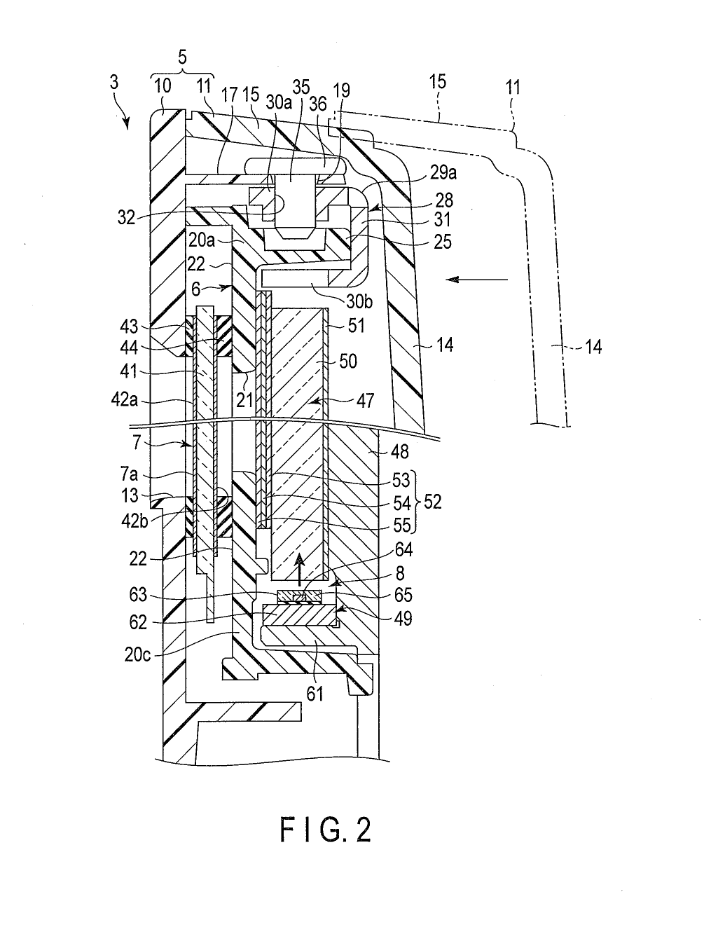

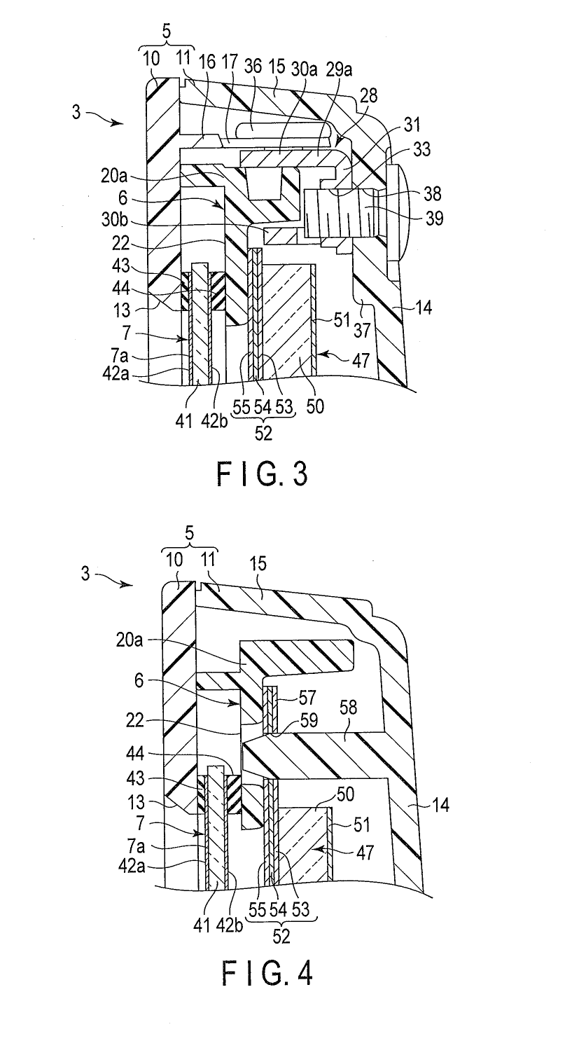

As shown in FIG. 2, FIG. 3, and FIG. 4, the television body 3 comprises a housing 5, a middle frame 6, a liquid-crystal display panel 7, and a backlight module 8.

The housing 5 has a flat rectangular box shape, for example. The housing 5 comprises a front bezel 10 and a back bezel 11. The front bezel 10 and the back bezel 11 are made of, for example, a synthetic resin material such as ABS resin.

The front bezel 10 is an example of a first cover, and forms a front wall of the housing 5. The front wall stands approximately vertically so as to face a TV watcher. As shown in FIG. 1A, the front bezel 10 has a shape like a rectangular frame which has first to fourth edge parts 12a, 12b, 12c, and 12d. The first edge part 12a and the third edge part 12c are extended horizontally in width directions of the housing 5, and are arranged parallel to one another at an interval maintained in height directions of the housing 5. The second edge part 12b and the fourth edge part 12d are extended vertically in height directions of the housing 5, and are arranged parallel to one another at an interval maintained in width directions of the housing 5.

Therefore, the first through fourth edge parts 12a, 12b, 12c, and 12d cooperatively form the rectangular opening 13. Specifically, the first edge part 12a defines an upper edge of the opening 13. The third edge part 12c defines a lower edge of the opening 13. The second edge part 12b defines a left edge of the opening 13. The fourth edge part 12d defines a right edge of the opening 13.

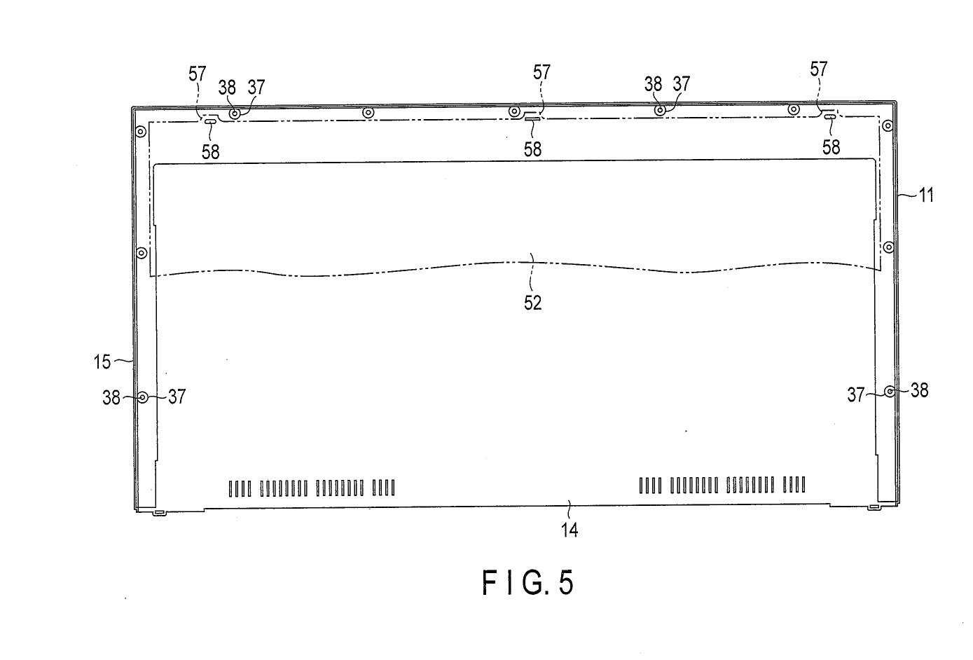

The back bezel 11 is an example of a second cover. The back bezel 11 is combined with the front bezel 10 so as to cover the front bezel 10 from behind. As shown in FIG. 2 and FIG. 5, the back bezel 11 comprises the back wall 14 and the peripheral wall 15. The back wall 14 comprises a rectangular shape and stands so as to face the front bezel 10. The peripheral wall 15 is protruded toward the front bezel 10 from an outer peripheral edge of the back wall 14 so as to continuously extend in circumferential directions of the back wall 14. A front end of the peripheral wall 15 is brought into contact with an outer-circumferential edge part of the front bezel 10.

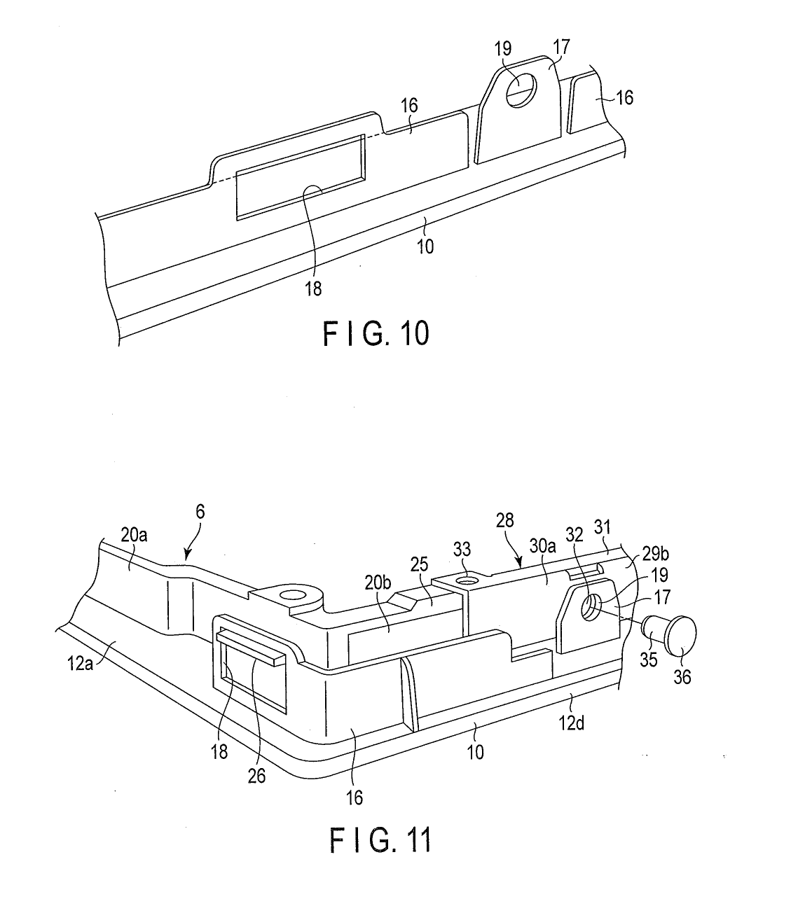

As shown in FIG. 2, FIG. 3, FIG. 10, and FIG. 11, the front bezel 10 comprises a plurality of wall parts 16 and a plurality of pin receiving parts 15. The wall parts 16 are protruded towards the back wall 14 of the front bezel 10 so as to surround the opening 13. A plurality of engagement holes 18 are formed in the wall part 16. Engagement holes 18 are provided at intervals along the circumferential directions of the front bezel 10.

The pin receiving parts 17 are provided at intervals along the peripheral directions of the front bezel 10 so as to protrude toward the back wall 14 of the back bezel 11 from the front bezel 10. Each of the pin receiving parts 17 is provided with a penetration hole 19.

The middle frame 6 is formed of, for example, a synthetic resin material such as ABS resin. The middle frame 6 is contained inside the housing 5 and is surrounded by the wall parts 16 of the front bezel 10. In other words, the middle frame 6 is positioned between the opening 13 of the front bezel 10, and the wall parts 16.

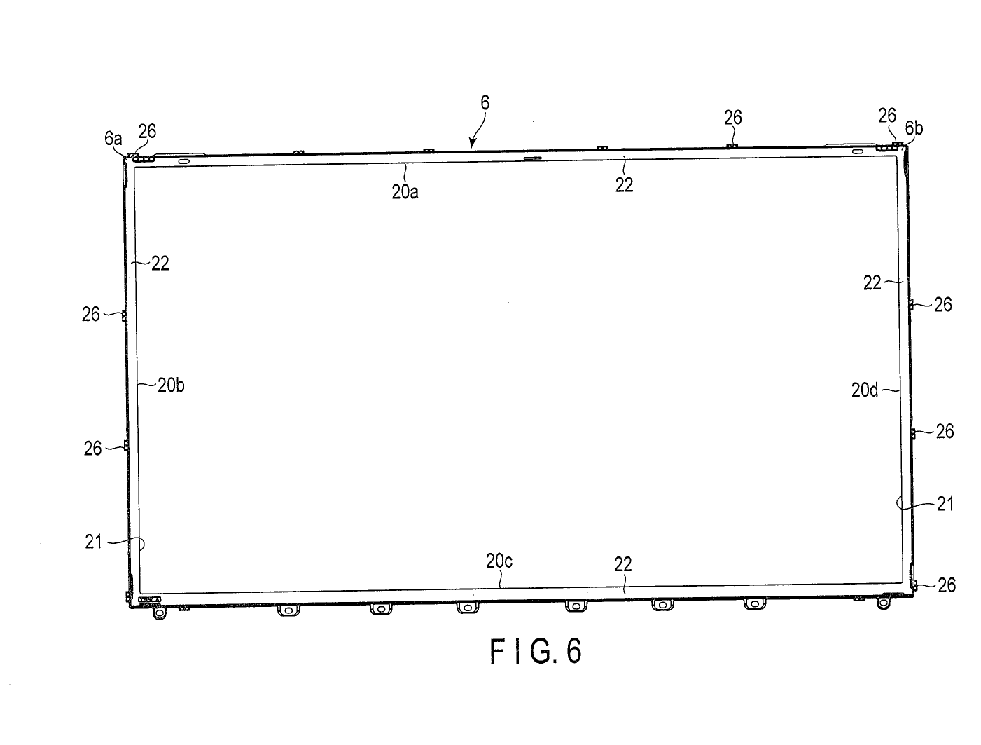

As shown in FIG. 6, the middle frame 6 has a shape like a rectangular frame which has first to fourth side parts 20a, 20b, 20c, and 20d. The first side part 20a extends along the first edge part 12a of the front bezel 10. The second side part 20b extends along the second edge part 12b of the front bezel 10. The third side part 20c extends along the third edge part 12c of the front bezel 10. The fourth side part 20d extends along the fourth edge part 12d of the front bezel 10. The first through fourth side parts 20a, 20b, 20c, and 20d cooperatively define a rectangular opening 21.

As shown in FIG. 6, the first through fourth side parts 20a, 20b, 20c, and 20d of the middle frame 6 each have a flat support face 22. The support faces 22 continue in the circumferential direction of the middle frame 6 so as to surround the opening 21, and are positioned on the same plane as each other. The support faces 22 face the front bezel 10.

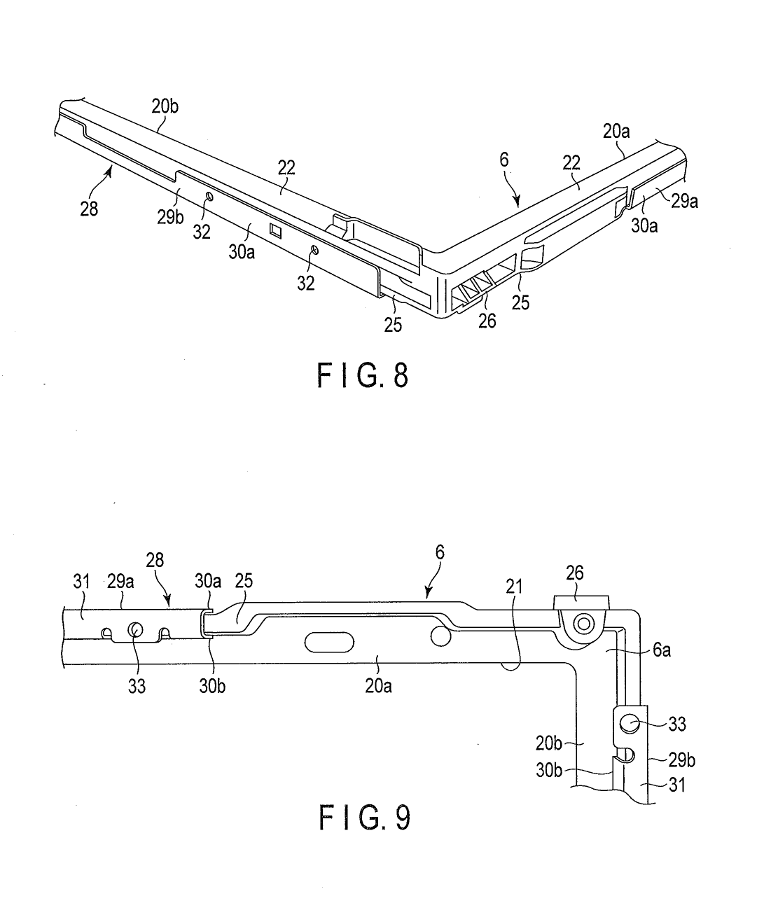

As shown in FIG. 2, FIG. 8, and FIG. 9, the first through fourth side parts 20a, 20b, 20c, and 20d of the middle frame 6 each comprise a support wall 25. The support walls 25 extend in the lengthwise directions of the first through fourth side parts 20a, 20b, 20c, and 20d, and are protruded toward the opposite side of the support faces 22.

As shown in FIG. 6, the middle frame 6 is provided with a plurality of engaging pawls 26. The engaging pawls 26 are protruded toward the outside of the middle frame 6 from the first through fourth side parts 20a through 20d of the middle frame 6. The engaging pawls 26 are provided at intervals along the circumferential directions of the middle frame 6.

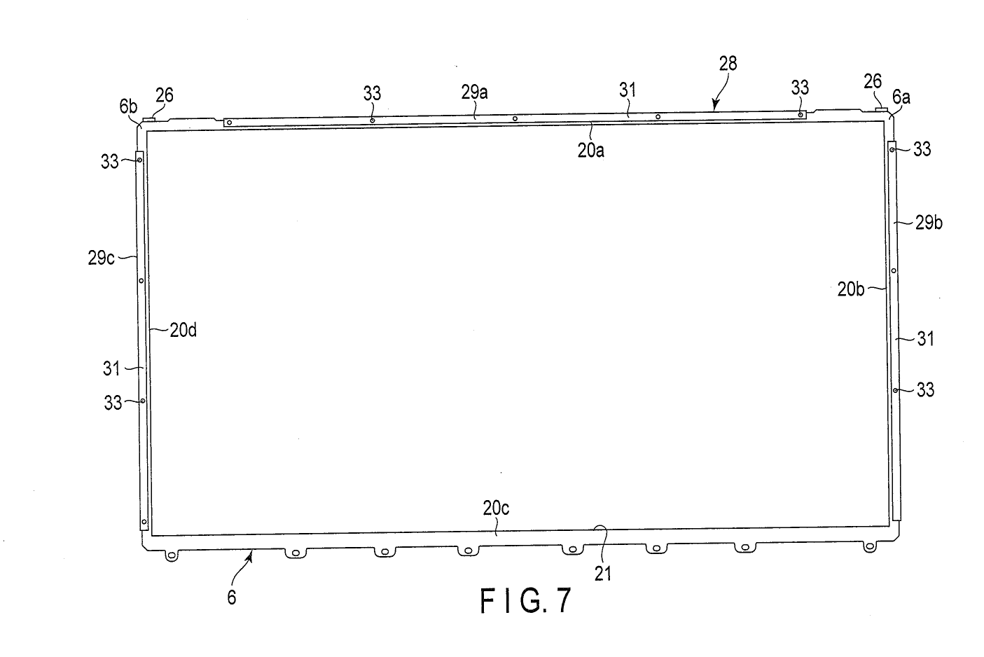

As schematically shown in FIG. 7, a reinforcing member 28 is attached to the middle frame 6. The reinforcing member 28 is configured by, for example, a metal plate which is more rigid than the middle frame 6. The reinforcing member 28 of the present embodiment is divided into first through third reinforcing metal fittings 29a, 29b, and 29c.

The first reinforcing metal fitting 29a is attached to the first side part 20a of the middle frame 6, and extends along the first side part 20a. The second reinforcing metal fitting 29b is attached to the second side part 20b of the middle frame 6, and extends along the second side part 20b. The third reinforcing metal fitting 29c is attached to the fourth side part 20d of the middle frame 6, and extends along the fourth side part 20d.

As shown in FIG. 7, an end part of the first reinforcing metal fitting 29a and an end part of the second reinforcing metal fitting 29b are distant from each other without reaching a corner part 6a which is defined between the first side part 20a and the second side part 20b of the middle frame 6.

Similarly, the other end part of the first reinforcing metal fitting 29a and an end part of the third reinforcing metal fitting 29c are distant from each other without reaching a corner part 6b which is defined between the first side part 20a and the fourth side part 20d of the middle frame 6.

The first through third reinforcing metal fittings 29a to 29c basically have an approximately common shape. Therefore, in the present embodiment, the first reinforcing metal fitting 29a will be described as a representative. The second and third reinforcing metal fittings 29b and 29c will be referred to at the same reference signs as the fitting 29a and will be omitted from descriptions below.

As shown in FIG. 2, FIG. 3, and FIG. 9, the first reinforcing metal fitting 29a comprises a pair of clamp parts 30a and 30b which sandwiches the support wall 25 of the middle frame 6, and a link part 31 which connects side edges of the clamp parts 30a and 30b. The first reinforcing metal fitting 29a is engaged in the support wall 25 so as to cover the support wall 25 from behind the support face 22 of the middle frame 6. In this manner, the first reinforcing metal fitting 29a is integrated with the middle frame 6. As a result, the middle frame 6 made of resin is reinforced by the reinforcing member 28, to maintain the rectangular shape.

One clamp part 30a of the first reinforcing metal fitting 29a is positioned outside the first side part 20a of the middle frame 6. One clamp part 30a has a plurality of engaging holes 32. The engaging holes 32 are arranged at intervals in the lengthwise direction of the first reinforcing fitting 29a, corresponding to the penetration holes 19 of the pin receiving parts 17.

The link part 31 of the first reinforcing metal fitting 29a stands behind the middle frame 6 so as to face the back wall 14 of the back bezel 11. The link part 31 is provided with a plurality of engaging holes 33. The engaging holes 33 are arranged at intervals along lengthwise directions of the first reinforcing metal fitting 29a.

The middle frame 6 reinforced with the reinforcing member 28 is layered over the front bezel 10 so as to be positioned in a region surrounded by the wall parts 16 and the pin receiving parts 17 of the front bezel 10. In this manner, as shown in FIG. 11, the engaging pawls 26 of the middle frame 6 are elastically engaged in the engaging holes 18 of the wall parts 16.

As a result, the middle frame 6 is temporarily engaged on the front bezel 10. Where the middle frame 6 is temporarily engaged on the front bezel 10, relative positioning is performed between the middle frame 6 and the front bezel 10. Specifically, the engaging holes 32 of first through third reinforcing metal fittings 29a, 29b, and 29c are matched with the penetration holes 19 of the pin receiving parts 17, and the opening 21 of the middle frame 6 is aligned with the opening 13 of the front bezel 10.

As shown in FIG. 2 and FIG. 11, the middle frame 6 provided with the reinforcing member 28 is fixed to the front bezel 10 through a plurality of pins 35. The pins 35 are an example of a connecting member. The pins 35 are inserted in the engaging holes 32 of the first through third reinforcing metal fittings 29a, 29b, and 29c from the penetration holes 19 of the pin receiving parts 17. By such insertion as described, the position of the middle frame 6 relative to the front bezel 10 is fixed.

Further, the pins 35 each have a disk-like head 36. The head 36 is positioned above the pin receiving part 17, and is covered by the peripheral wall 15 of the back bezel 11. The peripheral wall 15 makes contact with or approaches the head 36, thereby pressing down the pin 35 so that the pin 35 may not fall out of the penetration hole 19 and the engaging hole 32.

As shown in FIG. 3 and FIG. 5, a plurality of seat parts 37 are formed on an outer circumferential part of the back wall 14 of the back bezel 11. The seat parts 37 are brought into contact with the link parts 31 of the first through third reinforcing metal fittings 29a, 29b, and 29c, when the back bezel 11 is combined with the front bezel 10. Also, the seat parts 37 respectively comprise insertion holes 38 which correspond to the screw holes 33 of the link parts 31.

A plurality of screws 39 are inserted in the insertion holes 38 behind the back bezel 11. The screws 39 are screwed into the screw holes 33 through the insertion holes 38. The back bezel 11 is fixed to the reinforcing member 28 by screwing, in a manner that the front bezel 10, the back bezel 11, and the middle frame 6 are combined integrally.

As shown in FIG. 2, the liquid-crystal display panel 7 is contained inside the housing 5. The liquid-crystal display panel 7 is a flat rectangular board. The liquid-crystal display panel 7 comprises a panel body 41, a first protection sheet 42a, and a second protection sheet 42b. The panel body 4 comprises a liquid crystal layer and a drive board.

The liquid-crystal display panel 7 has a screen 7a which displays images. The first protection sheet 42a is layered on the screen 7a of the liquid-crystal display panel 7. The second protection sheet 42b is layered on the back of the liquid-crystal display panel 7. The outer circumferential part of the liquid-crystal display panel 7 is inserted between the support faces 22 of the middle frame 6, and the front bezel 10.

According to the present embodiment, a first cushion material 43 is inserted between the front bezel 10 and the outer circumferential part of the liquid-crystal display panel 7. Further, the second cushion material 44 is inserted between the support faces 22 of the middle frame 6 and the outer circumferential part of the liquid-crystal display panel 7. The first and second cushion materials 43 and 44 each are configured by an elastic material such as a rubber sheet.

Accordingly, the liquid-crystal display panel 7 is elastically sandwiched between the front bezel 10 and the back face 22 of the middle frame 6, and the screen 7a is exposed to outside of the housing 5 from the opening 13.

As shown in FIG. 2, a backlight module 8 is contained inside the housing 5. The backlight module 8 comprises a light guide module 47, a thermal radiator plate 48, and a light source module 49.

The light guide module 47 is positioned behind the liquid-crystal display panel 7. The light guide module 47 comprises a light guide plate 50, a light reflection sheet 51, and a surface sheet 52. The light guide plate 50 is a rectangular plate with a size equivalent to the panel body 41 of the liquid-crystal display panel 7, and has a light transmissibility. The light guide plate 50 is inserted between the middle frame 6 and the back wall 14 of the back bezel 11, and faces the opening 21 of the middle frame 6.

The light reflection sheet 51 is layered on the back of the light guide plates 50. The surface sheet 52 comprises a first prism sheet 53, a second prism sheet 54, and an optical diffusion sheet 55. The first prism sheet 53 is layered on the surface of the light guide plate 50. The second prism sheet 54 is layered on the first prism sheet 53. The light diffusion sheet 55 is layered on the second prism sheet 54.

As indicated by a two-dot chain line in FIG. 5, extension parts 57 are formed at three positions of an upper edge of the surface sheet 52. As shown in FIG. 4, the extension parts 57 are extended beyond an upper edge of the light guide plate 50, and face the back wall 14 of the back bezel 11. The back wall 14 comprises three ribs 58 corresponding to the extension parts 57. The ribs 58 are engaged in slits 59 formed in the extension parts 57, and maintain the surface sheet 52 to the back wall 14 of the back bezel 11.

The extension part 57 positioned in the left end part of the upper edge of the surface sheet 52 is positioned at the corner part 6a defined between the first side part 20a and the second side part 20b of the middle frame 6. According to the present embodiment, an end part of the first reinforcing metal fitting 29a and an end part of the second reinforcing metal fitting 29b are distant from each other without reaching the corner part 6a which is defined between the first side part 20a and the second side part 20b of the middle frame 6. Therefore, neither the first reinforcing metal fitting 29a nor the second reinforcing metal fitting 29b exists at the position corresponding to the extension part 57 at the left end part of the upper edge of the surface sheet 52. Accordingly, the extension part 57 does not interfere with the first or the second reinforcing metal fittings 29a and 29b.

Similarly, the extension parts 57 positioned at the right end part of the upper edge of the surface sheet 52 is positioned at the corner part 6b defined between the first side part 20a and the fourth side part 20d of the middle frame 6. According to the present embodiment, the other end part of the first reinforcing metal fitting 29a and an end part of the third reinforcing metal fitting 29c are distant from each other without reaching the corner part 6b which is defined between the first side part 20a and the fourth side part 20d of the middle frame 6. Therefore, neither the first reinforcing metal fitting 29a nor the third reinforcing metal fitting 29c exists at the position corresponding to the extension part 57 at the right end part of the upper edge of the surface sheet 52. Accordingly, the extension part 57 does not interfere with the first or the third reinforcing metal fittings 29a and 29c.

The thermal radiator plate 48 of the backlight module 8 is made of, for example, a metal material such as aluminum which has excellent thermal conductivity. The thermal radiator plate 48 is supported by the back wall 14 of the back bezel 11. The thermal radiator plate 48 extends throughout a whole length of the light guide plate 50 so as to cover a lower part of the light guide plate 50. The thermal radiator plate 48 links between the second side part 20b and the fourth side part 20d of the middle frame 6, and thereby reinforces the third side part 20c of the middle frame 6. Further, a light-source support part 61 is formed at a lower end part of the thermal radiator plate 48. The light-source support part 61 faces a lower face of the light guide plate 50.

The light source module 49 is mounted on the light-source support part 61 of the thermal radiator plate 48. The light source module 49 comprises a base 62 and a plurality of light emitting parts 63 (only one of which is shown). The base 62 is configured by a metal plate extending throughout the whole length of the light guide plate 50. The base 62 is set on the light-source support part 61, and is thermally connected to the thermal radiator plate 48.

Light emitting parts 63 are arranged in line at intervals along lengthwise directions of the base 62. Each of the light emitting parts 63 comprises a light emitting diode 64 and a sealing material 65. The sealing agent 65 is made of a transparent resin material including a phosphor material. The sealing material 65 wraps the light emitting diode 64.

As indicated by an arrow in FIG. 2, light emitted from each of the light emitting diodes 64 of the light source module 49 penetrates the sealing material 65, and enters into the light guide plate 50 from the lower face of the light guide plate 50. Light incident on the light guide plate 50 penetrates through the first prism sheet 53, second prism sheet 54, and optical diffusion sheet 55, and travels toward the liquid-crystal display panel 7.

Part of the light incident on the light guide plate 50, which travels toward the back bezel 11, is reflected by the light reflection sheet 51, then penetrates through the first prism sheet 53, second prism sheet 54, and optical diffusion sheet 55, and travels toward the liquid-crystal display panel 7. Accordingly, light is irradiated from the light guide module 47 toward the liquid-crystal display panel 7, and visibility of the image displayed on the screen 7a of the liquid-crystal display panel 7 is up.

According to the liquid crystal television 1 having such a configuration, the middle frame 6 which cooperates with the front bezel 10 to sandwich the outer circumferential part of the liquid-crystal display panel 7 is reinforced with the reinforcing member 28. Therefore, the middle frame 6 can be made of a synthetic resin material which less aggressively touches the liquid-crystal display panel 7. Therefore, when maintaining the liquid-crystal display panel 7 with the middle frame 6, the liquid-crystal display panel 7 is hardly damaged.

In addition, the first through third reinforcing metal fittings 29a, 29b, and 29c which form the reinforcing member 28 are attached to the support wall 25 protruded to the side opposite to the support face 22. Therefore, the first through third reinforcing metal fittings 29a, 29b, and 29c are distant from the support face 22, and do not interfere with the liquid-crystal display panel 7 on the support face 22.

As a result, in spite of reinforcing the middle frame 6 with the metal reinforcing member 28, the reinforcing member 28 does not damage the liquid-crystal display panel 7.

Further, according to the present embodiment, rigidity of the middle frame 6 can be securely maintained by existence of the reinforcing member 28. In this manner, the middle frame 6 is maintained in a shape of surrounding the outer circumferential part of the liquid-crystal display panel 7. Accordingly, when sandwiching the outer circumferential part of the liquid-crystal display panel 7 between the middle frame 6 and the front bezel 10, the middle frame 6 can be prevented from deformation. Therefore, workability at the time of assembling the liquid crystal television 1 can be excellently maintained.

In addition, according to the present embodiment, the middle frame 6 is fixed to the front bezel 10 only by a service work of engaging the pins 35 in the engaging holes 32 of the reinforcing member 28 from the penetration holes 19 of the pin receiving parts 17. Therefore, when fixing the middle frame 6 to the front bezel 10, troublesome and laborious service work such as tightening screws is not required at all. Therefore, workability at the time of assembling the liquid crystal television 1 can be improved.

In addition, when the back bezel 11 is combined with the front bezel 10, the pins 35 are pressed by the peripheral wall 15 of the back bezel 11 so as not to fall out of the penetration holes 19 and the engaging holes 32. Therefore, any special configuration for preventing the pins 35 from falling is not required, and the structure of the middle frame 6 and the front bezel 10 can accordingly be simplified.

According to the present embodiment, the reinforcing member which reinforces the middle frame is divided into the first through third reinforcing metal fittings. However, the reinforcing member may alternatively have an integral structure which continues in the circumferential directions of the middle frame.

Further, the above embodiment has described the liquid crystal television as an example of an electronic apparatus. The electronic apparatus, however, is not limited to a liquid crystal television. For example, the present embodiment is widely applicable to notebook-type or slate-type portable computers or other types of electronic apparatuses such as smart phones.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a housing which comprises a front bezel provided with an opening;
a display panel which is contained in the housing and is exposed from the opening;
a middle frame contained in the housing and comprising a support face which supports an outer circumferential part of the display panel, and the middle frame is configured to sandwich and hold the outer circumferential part of the display panel between the support face and the front bezel; and
a reinforcing member which is attached to the middle frame and reinforces, the middle frame being fixed to the front bezel through a connecting member.

2. The television of claim 1, wherein the reinforcing member is positioned in a side opposite to the support face in relation to the middle frame.

3. The television of claim 1, wherein the front bezel comprises a wall part surrounding the middle frame, the middle frame has a plurality of engaging pawls which are engaged on the wall part, and the middle frame is temporarily engaged on the front bezel by making the engaging pawls engage on the wall part.

4. The television of claim 3, wherein the front bezel comprises a receiving part protruded toward the reinforcing member, and the connecting member is engaged so as to link between the receiving part of the front bezel and the reinforcing member.

5. The television of claim 4, wherein the housing comprises a back bezel combined with the front bezel so as to cover the front bezel from behind, and the back bezel is configured to press the connecting member to prevent the connecting member from falling out of the receiving part and the reinforcing member, when the back bezel is combined with the front bezel.

6. The television of claim 5, wherein the back bezel is fixed to the reinforcing member by a plurality of screws, with the reinforcing member combined with the front panel.

7. The television of claim 1, wherein the front bezel and the middle frame are made of a resin material and the reinforcing member is made of a metal material.

8. The television of claim 1, further comprising:
a first cushion material inserted between the front bezel and the outer circumferential part of the display panel; and
a second cushion material inserted between the support face of the middle frame and the outer circumferential part of the display panel.

9. A television comprising:
a housing;
a display panel contained in the housing;
a middle frame contained in the housing and configured to sandwich and hold an outer circumferential part of the display panel between the middle frame and a front wall of the housing; and
a reinforcing member configured to reinforce the middle frame and fixed to the housing.

10. The television of claim 9, wherein the middle frame comprises first through fourth side parts along the outer circumferential part of the display panel, and the reinforcing member is provided on at least one of the first through fourth side parts.

11. The television of claim 9, wherein the front wall of the housing comprises a wall part surrounding the middle frame, the middle frame comprises a plurality of engaging pawls which are detachably engaged on the wall part, and the middle frame is held on the housing by making the engaging pawls engage on the wall part.

12. The television of claim 11, wherein the housing comprises a pin receiving part protruded from the front wall toward the reinforcing member, and the middle frame is fixed to the housing by a pin which links between the reinforcing member and the pin receiving part,

13. The television of claim 12, wherein the housing comprises a first cover comprising the front wall, and a second cover combined with the first cover, and the second cover is configured to press the pin and prevent the pin from falling out of the pin receiving part and the reinforcing member, when the second cover is combined with the first cover.

14. The television of claim 13, wherein the second cover is fixed to the reinforcing member with the second cover combined with the first cover.

15. The television of claim 13, further comprising a light guide module provided behind the display panel, and a light source module which illuminates the light guide module with light.

16. The television of claim 15, wherein the light guide module and the light source module are contained between the middle frame and the second cover.

17. An electronic apparatus comprising:
a housing comprising a front wall;
a panel contained in the housing;
a middle frame contained in the housing and comprising a support face which supports an outer circumferential part of the panel, and the middle frame is configured to sandwich and hold the outer circumferential part of the panel between the support face and the front wall; and
a reinforcing member attached to the middle frame so as to reinforce the middle frame, and the reinforcing member is fixed to the front wall.

18. The electronic apparatus of claim 17, wherein the housing comprises a pin receiving part protruded from the front wall toward the reinforcing member, and the middle frame is fixed to the housing by a pin which links between the reinforcing member and the pin receiving part.

19. The electronic apparatus of claim 18, wherein the housing comprises a first cover comprising the front wall, and a second cover combined with the first cover, and the second cover is configured to press the pin and prevent the pin from falling out of the pin receiving part and the reinforcing member, when the second cover is combined with the first cover.

20. The electronic apparatus of claim 17, wherein the middle frame comprises first through fourth side parts along the outer circumferential part of the panel, and the reinforcing member is provided on at least one of the first through fourth side parts.
